(19) United States
(12) Patent Application Publication
(10) Pub. No.: US 2018/0323063 A1
(43) Pub. Date: Nov. 8, 2018

(54) METHOD AND APPARATUS FOR USING SUPERCRITICAL FLUIDS IN SEMICONDUCTOR APPLICATIONS

(71) Applicant: Applied Materials, Inc., Santa Clara, CA (US)

(72) Inventors: Jean DELMAS, Santa Clara, CA (US); Steven VERHAVERBEKE, San Francisco, CA (US)

(21) Appl. No.: 15/586,208

(22) Filed: May 3, 2017

(51) Int. Cl. H01L 21/02; H01L 21/67; B08B 7/00; F25J 3/02

(52) U.S. Cl. CPC H01L 21/02101; H01L 21/67023; F25J 2220/02; F25J 3/0266; B08B 7/0021

(57) ABSTRACT

A method and apparatus for processing a substrate is provided. A feed stream of carbon dioxide liquid is supplied under pressure from a feed supply to a purification vessel. The carbon dioxide liquid in the purification vessel is distilled to form a purified carbon dioxide gas in a single stage distillation process. The processing method includes condensing the purified carbon dioxide gas in the condenser by heat exchange with a refrigerant from a refrigeration system to form a purified carbon dioxide liquid. The purified carbon dioxide liquid is heated to a target temperature above a critical point to change the purified carbon dioxide liquid to a supercritical carbon dioxide fluid. The processing method includes using the supercritical carbon dioxide fluid to clean a substrate disposed in a processing chamber.

### BACKGROUND

### Field

Embodiments generally relate to methods and apparatuses producing a purified liquid and using a supercritical fluid produced from the purified liquid in semiconductor applications. More particularly, embodiments relate to methods and apparatuses for purifying carbon dioxide and using the purified carbon dioxide in its supercritical fluid state to process substrates.

### Description of the Related Art

Carbon dioxide in its supercritical fluid state has been used in cleaning applications for substrates and other semiconductor applications. The advantages of supercritical carbon dioxide over organic solvents include the unique properties of supercritical fluids and the reduced environmental risks in the use of carbon dioxide. For substances which exhibit supercritical fluid properties, when the substance is above its critical point (critical temperature and critical pressure), the phase boundary between the gas phase and liquid phase disappears, and the substance exists in a single supercritical fluid phase. In the supercritical fluid phase, a substance assumes some of the properties of a gas and some of the properties of a liquid. For example, supercritical fluids have diffusivity properties similar to gases but solvating properties similar to liquids. Therefore, supercritical fluids have good cleaning properties.

Semiconductor applications require a high level of purity for carbon dioxide used. There are different carbon dioxide grades with each carbon dioxide grade having different levels of purity. For example beverage grade carbon dioxide may be supplied in canisters for use in semiconductor products by gas suppliers. One problem is that the carbon dioxide purity level for beverage grade carbon dioxide may have too large a variation for different canisters from a single supplier and from different suppliers. Using different grades of carbon dioxide from suppliers also has disadvantages due to inconsistent purity levels and high costs. Therefore, there is a need for apparatuses and methods for purifying carbon dioxide and using the purified carbon dioxide in its supercritical fluid state to process substrates.

### SUMMARY

Embodiments of the disclosure describe a method and apparatus of processing a substrate. In one embodiment, a processing method includes providing a feed supply of a carbon dioxide liquid. A feed stream of carbon dioxide liquid is supplied under pressure from the feed supply to a purification vessel of a purification system. The processing method includes supplying heat to the carbon dioxide liquid in the purification vessel by a distillation heater in the purification vessel. The feed stream in the purification vessel is distilled to form a purified carbon dioxide gas in a single stage distillation process. The purified carbon dioxide gas is supplied from the purification vessel to a condenser through a distillation fluid line. The processing method includes condensing the purified carbon dioxide gas in the condenser by heat exchange with a refrigerant from a refrigeration system 362 to form a purified carbon dioxide liquid. The purified carbon dioxide liquid is heated to a target temperature above a critical point to change the purified carbon dioxide liquid to a supercritical carbon dioxide fluid. The processing method includes using the supercritical carbon dioxide fluid to clean a substrate disposed in a processing chamber.

In another embodiment, a processing method includes supplying under pressure a feed stream of a carbon dioxide liquid from the feed supply to a purification system having a purification vessel, a condenser, a refrigeration system 362, and a product storage vessel. The process method includes distilling the feed stream in the purification vessel to form a purified carbon dioxide gas in a single stage distillation process. The purified carbon dioxide gas is supplied from the purification vessel to the condenser through a distillation fluid line. The processing method includes condensing the purified carbon dioxide gas in the condenser by heat exchange with a refrigerant from a refrigeration system 362 to form a purified carbon dioxide liquid. The purified carbon dioxide liquid is supplied to the product storage vessel. The processing method includes heating the purified carbon dioxide liquid from the purification system to a target temperature above a critical point to change the purified carbon dioxide liquid to a supercritical carbon dioxide fluid. The supercritical carbon dioxide fluid is used to clean a substrate disposed in a processing chamber.

In another embodiment, a processing system for processing a substrate includes a purification system for purifying a feed supply of carbon dioxide liquid disposed in a feed supply container. The purification system includes a distillation unit having a purification vessel coupled to the feed supply container. The distillation unit includes a distillation heater disposed in the purification vessel for heating the carbon dioxide liquid disposed therein. The distillation unit is configured to distill a feed stream of carbon dioxide liquid from the feed supply container in a single stage distillation process to form a purified carbon dioxide gas. A condenser is coupled to the distillation unit by a distillation fluid line. The condenser is configured to receive the purified carbon dioxide gas supplied by the distillation gas line and to condense the purified carbon dioxide gas in the condenser by heat exchange with a refrigerant to form a purified carbon dioxide liquid. A refrigeration system 362 coupled to the condenser by a refrigerant supply line to supply the refrigerant to the condenser. A processing chamber for processing a substrate is disposed therein and coupled to the purification system by a purified carbon dioxide supply line. The purified carbon dioxide supply line supplies a purified carbon dioxide fluid to the processing chamber. A heating element is configured to heat the purified carbon dioxide liquid to a target temperature above a critical point to change the purified carbon dioxide liquid to a supercritical carbon dioxide fluid.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only selected implementations of this disclosure and are therefore not to be considered limiting of its scope, for the disclosure may admit to other equally effective implementations.

FIG. 1 depicts a schematic for a processing system according to one embodiment with a chamber adapted to apply a supercritical fluid to a substrate in which the fluid is heated within the chamber.

FIG. 2 depicts a schematic for a processing system according to one embodiment with a chamber adapted to apply a supercritical fluid to a substrate in which the fluid is heated in-line.

FIG. 3 depicts a schematic of a purification system for the processing system according to one embodiment.

To facilitate understanding, identical reference numerals have been used, wherever possible, to designate identical elements that are common to the Figures. Additionally, elements of one implementation may be advantageously adapted for utilization in other implementations described herein.

### DETAILED DESCRIPTION

Embodiments herein generally provide a method and apparatus for processing a substrate for semiconductor applications including cleaning of substrates with supercritical carbon dioxide fluid. The embodiments provide a processing system that includes a purification system having a distillation unit and condenser for purifying a feed supply containing carbon dioxide liquid to form a purified carbon dioxide liquid using a single stage distillation process. A distillation vessel supplies purified carbon dioxide gas to a condenser in the purification system. The condenser condenses the purified carbon dioxide gas to form the purified carbon dioxide liquid that is supplied to a product storage vessel. The purification system is coupled to a processing chamber. The purified liquid carbon dioxide from the purification system is heated to form a supercritical carbon dioxide fluid that is used in processing a substrate disposed in the processing chamber. A level indicating controller is coupled to the product storage vessel to detect the storage level of the purified carbon dioxide liquid and controls the flow rate of the purified carbon dioxide liquid supplied to the product storage vessel.

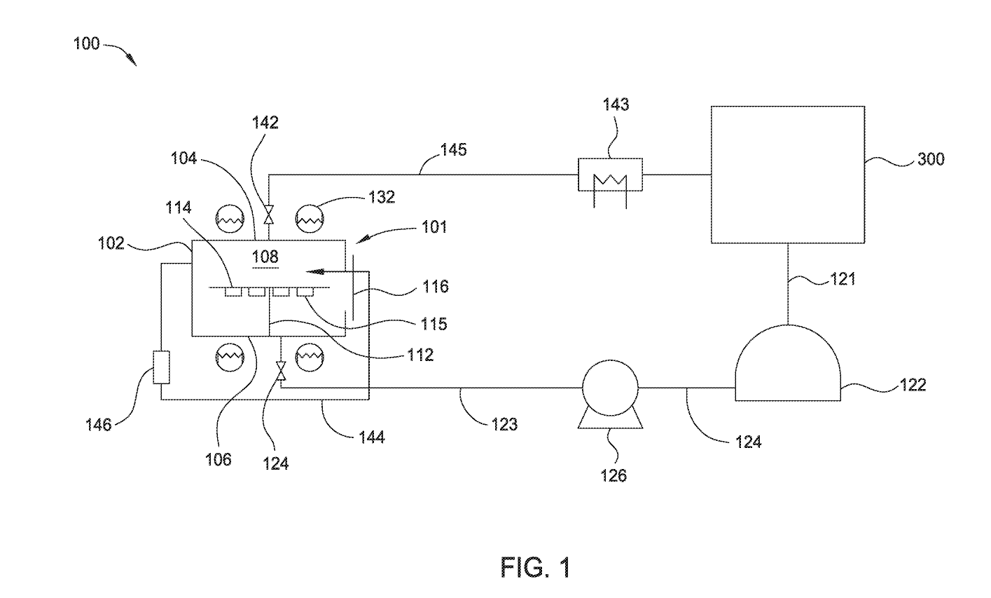

FIG. 1 is a schematic cross-sectional view of one embodiment of a processing system 100, configured to apply a supercritical carbon dioxide fluid to a substrate. The processing system 100 includes a processing chamber 101, a fluid supply 122, and a purification system 300. The purification system 300 supplies a purified carbon dioxide liquid to the fluid supply 122 for use in the processing chamber 101 having a substrate disposed therein. In some embodiments, the fluid supply 122 may be omitted and the purified carbon dioxide liquid is stored in the purification system 300. The purification system 300 provides the purified carbon dioxide fluid for use in a cleaning process for the substrate after a feed carbon dioxide fluid has undergone a purification process that eliminates contaminants from the feed carbon dioxide fluid.

The processing chamber 101 includes sidewalls 102, a top wall 104, and a bottom wall 106 which define an enclosure 108. In one embodiment, the volume of the enclosure 108 comprises a small volume to reduce the amount of fluid necessary to fill the enclosure 108. In one embodiment, the processing chamber 101 is adapted to process 300 mm diameter substrates and has a volume of about 10 liters or less, for example about 5 liters or less. The processing chamber 101 may include a slit valve 116 to provide access for a robot to transfer and receive substrates from the enclosure 108. In some embodiments, the processing chamber 101 may provide top loading or bottom loading access to transfer and receive substrates from the enclosure 108. A substrate support 112 comprising a platter 114 is adapted to support the substrate within the enclosure 108. In one embodiment, the platter 114 defines a substrate receiving surface for receiving the substrate. The platter 114 may be adapted to rotate the substrate during processing.

The processing chamber 101 may optionally further include one or more transducers 115. As shown, the transducers 115 are located on the substrate support 112 but may be located in other areas of the enclosure 108. The transducers 115 create acoustic or sonic waves directed towards the surface of a substrate to help agitate the purified carbon dioxide fluid. In other embodiments, the transducers 115 may comprise a rod, plunger, or plate located within the enclosure 108.

An inlet fluid supply line 123 couples the fluid supply 122 for storing the purified carbon dioxide liquid and the supply fluid inlet 124 to the processing chamber 101. A pump 126 may be disposed on the inlet fluid supply line 123 between the supply fluid inlet 124 and the fluid supply 122 for delivering the purified carbon dioxide liquid from the fluid supply 122 into the enclosure 108 of the processing chamber 101.

One or more heating elements 132 are disposed proximate or inside the processing chamber 101. The heating elements 132 may comprise electric elements, fluid channels for a heat control fluid, and/or other heating devices. The heating elements 132 heat the purified carbon dioxide fluid inside the enclosure 108 to a desired temperature. The processing chamber 101 may also optionally include cooling elements.

The processing chamber 101 may further include a loop 144 for re-circulating carbon dioxide fluid to and from the processing chamber 101. The loop 144 may further include a filter 146, such as an activated charcoal filter, to help purify the carbon dioxide fluid. In one aspect, the loop 144 helps produce a laminar flow of the carbon dioxide fluid within the enclosure 108 and helps prevent a stagnant fluid bath. It is believed that a laminar flow helps to sweep particles away from the substrate and to prevent particles from re-depositing on the substrate. The loop 144 may be omitted in some embodiments.

An exhaust fluid outlet 142 is coupled to the processing chamber 101 via an exhaust fluid line 145 for removal of an exhaust fluid from the enclosure 108. The exhaust fluid includes the carbon dioxide fluid that has been injected into the processing chamber 101 and used in processing the substrate. The exhaust fluid outlet 142 may release the exhaust fluid to atmosphere, may direct the exhaust fluid to storage, or may recycle the fluid for re-use.

As shown, the exhaust fluid outlet 142 is coupled to the purification system 300 and outputs the exhaust fluid to the purification system 300. Outputting the exhaust fluid to the purification system 300 provides for recycling the exhaust fluid. The purification system 300 recycles the exhaust fluid by feeding the exhaust fluid into the distillation vessel 310 to recycle the exhaust fluid. An exhaust fluid condenser 143 is coupled between the exhaust fluid outlet 142 and the purification system 300 to condense the exhaust fluid to form a carbon dioxide liquid prior to being directed to the purification system 300.

As shown, the supply fluid inlet 124 is disposed at a bottom wall 106 of the processing chamber 101 while the exhaust fluid outlet 142 is disposed at the top wall 104 of the processing chamber 101. Of course, the supply fluid inlet 124 and the exhaust fluid outlet 142 may be disposed at other areas of the walls 102, 104, 106 of the processing chamber 101. In addition, the supply fluid inlet 124 may be optionally coupled to nozzles, showerhead, or other device to direct the fluid towards the substrate.

One example of a method of processing a substrate with a carbon dioxide fluid in processing chamber 101 comprises transferring a substrate through the slit valve 116 to the substrate support 112 and closing the slit valve 116. Purified carbon dioxide liquid is pumped by pump 126 into the processing chamber 101 from the fluid supply 122 to a desired pressure of the carbon dioxide liquid within the enclosure 108. The supply fluid inlet 124 is closed and the heating elements 132 heat the purified carbon dioxide liquid to a target temperature so that the purified carbon dioxide liquid forms a supercritical carbon dioxide fluid. The term “supercritical carbon dioxide fluid” as used herein refers to a carbon dioxide fluid above its critical point. The carbon dioxide fluid is optionally agitated through application of the transducers 115 and/or rotation of the substrate. The carbon dioxide fluid is optionally re-circulated within the enclosure 108 through loop 144.

After the substrate has been processed with the carbon dioxide fluid for a desired time period, the exhaust fluid outlet 142 is opened and the carbon dioxide fluid is vented or released to atmosphere, directed to the exhaust fluid condenser 143, or directed to storage. In one embodiment, releasing the pressure of the processing chamber 101 causes the carbon dioxide fluid at a supercritical fluid state to be at a gas state which can be easily removed from the processing chamber 101 as an exhaust carbon dioxide fluid. The substrate may be optionally heated during venting to prevent cooling of the substrate and to prevent moisture uptake. Other methods of processing a substrate with a supercritical carbon dioxide fluid are also possible in processing chamber 101.

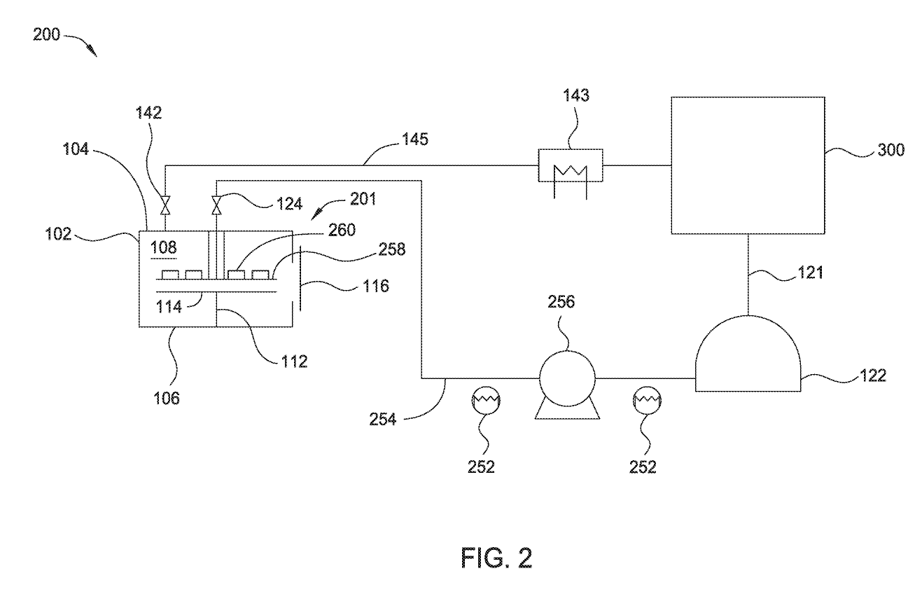

FIG. 2 is a schematic cross-sectional view of one embodiment of a processing system 200 having a processing chamber 201 adapted to apply a supercritical carbon dioxide fluid to a substrate in which the fluid is heated in-line. Some of the parts of processing system 200 of FIG. 2 are similar to the parts of processing chamber 101 of FIG. 1. As a consequence like part numerals have been used for clarity of description where appropriate.

The processing system 200 has one or more heating elements 252 for heating a supercritical carbon dioxide fluid supply line 254 coupling the fluid supply 122 and the processing chamber 201. A pump/compressor 256 may be disposed on the supercritical carbon dioxide fluid supply line 254 to deliver the fluid to the enclosure 108. The heating elements 252 may be disposed before and/or after the pump/compressor 256. The supercritical fluid supply line 254 is coupled to a fluid delivery device 258, such as a showerhead, nozzle, or plate, disposed above the substrate support 112. In one embodiment, the fluid is delivered as a supercritical carbon dioxide fluid by the fluid delivery device 258 (i.e. as opposed to delivering the fluid to the chamber and setting conditions inside the chamber to bring the fluid to a supercritical or dense fluid state). In one embodiment, the fluid exists as a supercritical carbon dioxide fluid at a partial volume of the enclosure 108 proximate the substrate surface. In another embodiment, a supercritical carbon dioxide fluid is supplied by the fluid delivery device 258 until the enclosure 108 is at a supercritical fluid state.

The fluid delivery device 258 optionally may include transducers 260 adapted to create acoustic or sonic waves directed towards the surface of a substrate to help agitate the fluid. In other embodiments, the transducers 260 may be disposed at other locations within the enclosure 108. In addition, the substrate support 112 may be adapted to rotate the substrate and/or the fluid delivery device may be adapted to rotate to help agitate the fluid. The processing chamber 201 may also optionally include heating and/or cooling elements proximate or inside the processing chamber 101.

One example of a method of processing a substrate with a carbon dioxide fluid in processing chamber 201 comprises transferring a substrate to the substrate support 112. Carbon dioxide is transferred by pump/compressor 256 from the fluid supply 122 through the supercritical fluid supply line 254 at a desired pressure. The heating elements 252 heat the carbon dioxide to a desired temperature as the fluid is being transferred though the supercritical fluid supply line 254. The fluid delivery device 258 delivers a supercritical carbon dioxide fluid and/or a dense carbon dioxide fluid to the substrate. The carbon dioxide is optionally agitated through application of the transducers 260, rotation of the substrate, and/or rotation of the fluid delivery device. The enclosure 108 may be pressurized or unpressurized during application of the supercritical carbon dioxide fluid and/or dense carbon dioxide fluid by the fluid delivery device 258. After application of the carbon dioxide to the substrate, the carbon dioxide is vented or released to atmosphere, directed to the condenser 143, or directed to storage. The substrate may be optionally heated during venting to prevent cooling of the substrate and to prevent moisture uptake. Other methods of processing a substrate with a supercritical carbon dioxide fluid are also possible in processing chamber 201.

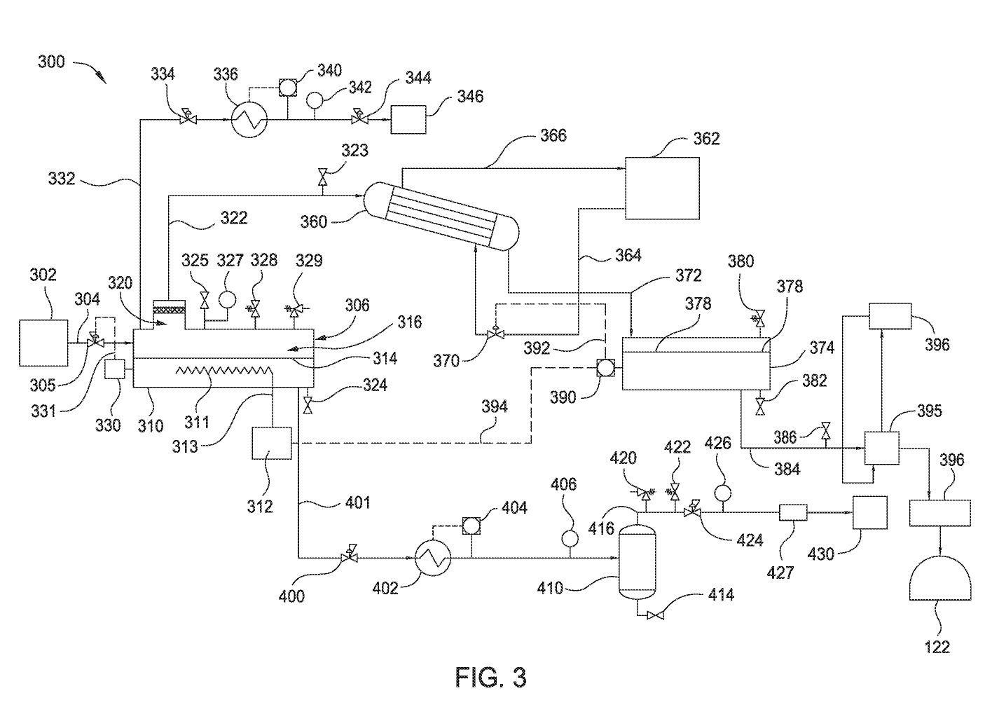

FIG. 3 depicts a schematic of a purification system 300 for the processing system 100, 200. The purification system 300 is supplied with a feed fluid from a carbon dioxide feed supply 302. The feed fluid is a carbon dioxide liquid. The carbon dioxide liquid from the carbon dioxide feed supply 302 may be stored at a pressure of 50-70 bar absolute (725 psia-1015 psia) and in the liquid state at no more than 10 degrees Celsius (50 degrees Fahrenheit). The feed fluid is a beverage-grade carbon dioxide liquid. The carbon dioxide liquid is stored in pressurized canisters or other pressurized containers capable of storing carbon dioxide liquid at pressure. In one embodiment, the carbon dioxide liquid meets the International Society of Beverage Technologists (ISBT) 2010 Bulk Carbon Dioxide Quality Guidelines and Analytical Methods Reference for purity established by the ISBT. In an embodiment, the feed supply of carbon dioxide liquid has an impurity level that does not exceed 5 parts per million by weight of non-volatile organic compounds.

In alternative embodiments, other grades of carbon dioxide liquids may be used for the feed fluid depending on the specific design features and applications for the processing system 100, 200. In other embodiments, the carbon dioxide liquid may be stored in a pressurized container such as an insulated storage tank that is pressurized with a booster pump (not shown).

Purging the purification system 300 with a cleaning carbon dioxide gas prior to supplying the feed stream of carbon dioxide liquid from the carbon dioxide feed supply 302 to the distillation vessel 310 is also performed in some embodiments. The cleaning carbon dioxide gas has a minimum purity of 99.99 percent.

The carbon dioxide liquid from the carbon dioxide feed supply 302 is supplied to a distillation unit 306 through a feed control valve 305 in a feed line 304. The carbon dioxide liquid from the carbon dioxide feed supply 302 is supplied to the distillation unit 306 from the feed supply as a feed stream stored at a pressure of 50-70 bar absolute (725 psia-1015 psia) and in the liquid state at no more than 10 degrees Celsius (50 degrees Fahrenheit). The feed line 304 is insulated and pressurized to maintain the feed fluid at a temperature and pressure such that the carbon dioxide liquid remains in a liquid state. The distillation unit 306 provides for a single station distillation of the feed fluid. The distillation unit 306 includes a distillation vessel 310 used to hold the carbon dioxide liquid supplied from carbon dioxide feed supply 302. The distillation vessel 310 is pressurized and maintains the carbon dioxide liquid at a pressure range of 20-100 bar absolute (290 psia-14450 psia) and a temperature range of −20 to 30 degrees Celsius (−4 to 86 degrees Fahrenheit). In one example, the distillation vessel 310 is pressurized and maintains the carbon dioxide liquid at a pressure of 45 bar absolute (290 psia-14450 psia) and a temperature of 10 degrees Celsius (50 degrees Fahrenheit).

A distillation heater 311 is located at a bottom section of the distillation vessel 310 below a distillation normal liquid level 314 for the carbon dioxide liquid. As shown in FIG. 3, the carbon dioxide liquid fills the distillation vessel 310 from the bottom of the distillation vessel 310 to the distillation normal liquid level 314. The distillation heater 311 is connected to a heater controller 312 by a heater control line 313. The heater controller 312 controls the distillation heater 311 so that the distillation heater 311 heats the carbon dioxide liquid to an evaporation temperature where at least a portion of the carbon dioxide liquid converts to a purified carbon dioxide gas. The purified carbon dioxide gas fills a top section of the distillation vessel 310 that is disposed above the carbon dioxide liquid, shown to be at the distillation normal liquid level 314 in FIG. 3. A distillation drain 324 is provided at the bottom of the distillation vessel 310. A startup pressurized purge connection 325, a distillation pressure indicator 327, a distillation high point purge vent 328, and a distillation pressure relief valve 329 are provided at the top of the distillation vessel 310.

A distillation level indicating controller 330 is coupled to the distillation vessel 310 and detects a level or amount of the carbon dioxide liquid in the distillation vessel 310. The distillation level indicating controller 330 generates a distillation level control signal that corresponds to the level of the carbon dioxide fluid in the distillation vessel 310. The distillation level indicating controller 330 is coupled to the feed control valve 305 in the feed line 304 via a feed supply control line 331. The distillation level indicating controller 330 is configured to communicate the distillation level control signal to the feed control valve 305 in the feed line 304 via the feed supply control line 331. The feed control valve 305 controls the flow of the feed stream of the carbon dioxide liquid from the carbon dioxide feed supply 302 in response to the distillation level control signal to maintain a distillation normal liquid level 314 for the carbon dioxide liquid in the distillation vessel 310. A distillation normal liquid level 314 is maintained in distillation vessel 310 by adding the carbon dioxide liquid from the carbon dioxide feed supply 302, as needed.

A pressure control line 332 with a distillation back-pressure regulator 334, a pressure control vent heater 336, and a distillation pressure vent 346 is coupled to a top section of the distillation vessel 310. The distillation back-pressure regulator 334 releases purified carbon dioxide gas to the pressure control vent heater 336 when the pressure in the distillation vessel 310 exceeds a predetermined pressure level. The pressure control vent heater 336 heats the carbon dioxide gas, and the output of the pressure control vent heater 336 is coupled to the distillation pressure vent 346. A heater level indicating controller 340 is coupled to and controls the pressure control vent heater 336. A pressure indicator 342 and a heater back pressure regulator are coupled to the pressure control line 332.

Contaminants in the carbon dioxide feed remain in the carbon dioxide liquid that remains in the distillation vessel 310. Contaminants in the carbon dioxide liquid are removed from the distillation vessel 310 are removed by a liquid purge line 401. The liquid purge line 401 is coupled to a purge vent heater 402 through a forward pressure regulator 400 and includes purge line pressure indicator 406. The purge vent heater 402 heats the carbon dioxide liquid and is controlled by a purge level indicating controller 404. An output from the purge vent heater 402 is supplied to the vent knockout 410. The vent knockout 410 has a knockout valve 414 that drains carbon dioxide liquid including non-volatile organic compounds from a bottom section of the vent knockout 410. The top section of the vent knockout 410 contains a carbon dioxide gas from the purge vent heater 402. The carbon dioxide gas from the liquid purge line 401 is coupled to a knockout gas line 416 and is vented through a purge vent 430. The liquid purge line 401 includes a pressure relief valve 420, a high point purge vent 422, a forward pressure regulator 424, a pressure indicator 426, and a mass flow controller 427.

The purified carbon dioxide gas in the distillation vessel 310 exits through a distillation port 320 and to a distillation fluid line 322. A fluid line high point pressure vent 323 is provided in the distillation fluid line 322. The purified carbon dioxide gas exiting the distillation vessel 310 flows into a purification system condenser 360. The purification system condenser 360 is connected to a refrigeration system 362 used to cool the purified carbon dioxide gas in the purification system condenser 360. The refrigeration system 362 may be a packaged glycol chiller. A refrigerant fluid from the refrigeration system 362 flows through a refrigerant supply line 364 to purification system condenser 360 to remove heat and lower the temperature of the purified carbon dioxide gas in the purification system condenser 360. The refrigerant fluid passing through the purification system condenser 360 flows into a refrigerant return line 366 and to the refrigeration system 362 where heat is removed from the refrigerant. The purified carbon dioxide gas converts to a purified carbon dioxide liquid when a sufficient amount of heat is removed from the purified carbon dioxide gas by the refrigerant passing through the purification system condenser 360.

The purified carbon dioxide liquid from the purification system condenser 360 is supplied to a product storage vessel 374 through a condenser liquid supply line 372. The purification system condenser 360 can be disposed at a location where the purification system condenser 360 is positioned higher than the product storage vessel 374 and the distillation vessel 310 of the purification system 300. By positioning the purification system condenser 360 higher than the product storage vessel 374, gravity assists the flow of purified carbon dioxide liquid from the purification system condenser 360 to the product storage vessel 374. By positioning the purification system condenser 360 higher than the distillation vessel 310, any purified carbon dioxide liquid that may form in the distillation fluid line 322 is assisted by gravity to flow to the distillation vessel 310 to help prevent blockage of the distillation fluid line 322.

The purified carbon dioxide liquid is contained in the product storage vessel 374. The purified carbon dioxide liquid has had impurities removed by the distillation unit 306 to generate a purified carbon dioxide liquid. A storage vessel drain 382 is coupled to the bottom of the product storage vessel 374 and a high point purge vent 380 is coupled to the top of the product storage vessel 374.

In an embodiment, the feed supply of carbon dioxide liquid has a target impurity level of 5 parts per million by weight of non-volatile organic compounds. A target impurity level for the feed supply of 5 parts per million by weight of non-volatile organic compounds is an impurity level for the carbon dioxide liquid that does not exceed 5 parts per million by weight of non-volatile organic compounds. For a feed supply having the target impurity level of 5 parts per million by weight for the non-volatile organic compounds, the purification system 300 removes contaminants to produce the purified carbon dioxide liquid with an impurity level that does not exceed 0.05 parts per million by weight of non-volatile organic compounds. The purification system 300 removes at least ninety-nine percent of non-volatile organic compounds for a feed supply 302 having the target impurity level of 5 parts per million by weight of non-volatile organic compounds.

The purified carbon dioxide liquid from the product storage vessel 374 flows to a subcooler 395 via a product storage output line 384. A system purge valve 386 is coupled to the product storage output line 384. By passing the purified carbon dioxide liquid through the subcooler 395, the subcooler 395 functions to reduce a temperature of the purified carbon dioxide liquid to maintain the purified carbon dioxide liquid in a liquid state.

A subcooler refrigerant system 396 is coupled to the subcooler 395 for supplying a refrigerant to the subcooler 395 to remove heat from the purified carbon dioxide liquid flowing through the subcooler 395. The purified carbon dioxide liquid from the subcooler 395 is supplied to an adsorption filter 398. The adsorption filter 398 may use materials such as molecular sieves, silica gel, and activated carbons. The adsorption filter 398 acts to remove additional contaminants from the purified carbon dioxide liquid in the purification system 300. The purification system 300 supplies the purified liquid carbon dioxide from the adsorption filter 398 to the fluid supply 122 for processing the substrate in the processing chamber 101, 201, as shown in FIGS. 1-2. The purification system 300 is coupled to the fluid supply 122 through a purification system supply line 121.

The purification system 300 is configured to replace purified carbon dioxide liquid that is outputted from the product storage vessel 374 for use in the processing chamber 101 to maintain a normal purified liquid storage level 378, as shown in FIG. 3. The normal purified liquid storage level 378 is a selected level or amount of purified carbon dioxide liquid in the product storage vessel 374 that is ready for use in processing substrates. The purification system condenser 360 supplies the purified carbon dioxide liquid to the product storage vessel 374, and the rate that purification system condenser 360 supplies the purified carbon dioxide liquid can be varied.

One factor for controlling the flow rate of purified carbon dioxide liquid from the purification system condenser 360 to the product storage vessel 374 is the rate that the purified carbon dioxide gas is condensed in the purification system condenser 360. Another factor for controlling the flow rate of purified carbon dioxide liquid from the purification system condenser 360 to the product storage vessel 374 is the rate of purified carbon dioxide gas formed by the distillation unit 306 and supplied to the purification system condenser 360.

A product level indication controller 390 is coupled to the product storage vessel 374 to control the rate of purified carbon dioxide liquid being supplied from the purification system condenser 360 to the product storage vessel 374 to maintain a normal purified liquid storage level 378. To control the normal purified liquid storage level 378, the product level indication controller 390 detects a purified liquid storage level of the purified carbon dioxide liquid stored in the product storage vessel 374. The product level indication controller 390 generates a storage level control signal corresponding to the purified liquid storage level.

After generating the storage level control signal, the product level indication controller 390 communicates the storage level control signal to the heater controller 312 for the distillation vessel 310 via heater controller line 394. The heater controller 312 is configured to adjust a heat output of the distillation heater 311 in response to the storage level control signal. Adjusting the heat output of the distillation heater 311 controls the evaporation rate of the carbon dioxide liquid in the distillation vessel 310 and the rate of purified carbon dioxide gas supplied from the distillation vessel 310 to the purification system condenser 360.

For example, the product level indication controller 390 sends a below-level control signal to the heater controller 312 when the liquid level of the product storage vessel 374 falls below the normal purified liquid storage level 378. The heater controller 312 responds to the below-level control signal by controlling the distillation heater 311 to increase the heat output of the distillation heater 311. Increasing the heat output of the distillation heater 311 increases the evaporation rate of the carbon dioxide liquid in the distillation vessel 310 so that an increased amount of purified carbon dioxide gas is supplied to the purification system condenser 360. The increased amount of purified carbon dioxide gas supplied to the purification system condenser 360 enables the purification system condenser 360 to increase the rate of purified carbon dioxide liquid produced by the purification system condenser 360 and supplied to the product storage vessel 374.

The product level indication controller 390 also communicates the storage level control signal to the refrigerant control valve 370 via condenser controller line 392. The product level indication controller 390 communicates control signals to the refrigerant control valve 370 that correspond to the liquid level of the product storage vessel 374. The refrigerant control valve 370 is configured to adjust a refrigerant flow rate to the purification system condenser 360 in response to the storage level control signal. Adjusting the refrigerant flow rate controls the rate that the purified carbon dioxide gas is condensed so as to adjust a supply of the purified carbon dioxide liquid supplied from the purification system condenser 360 to the product storage vessel 374.

For example, the product level indication controller 390 sends a below-level control signal to the refrigerant control valve 370 that the liquid level of the product storage vessel 374 has fallen below the normal purified liquid storage level 378. The refrigerant control valve 370 responds to the below-level control signal by continuing to supply or increasing the supply of refrigerant to the purification system condenser 360. Increasing the supply of refrigerant to the purification system condenser 360 results in the purification system condenser 360 continuing or increasing the rate of condensing carbon dioxide gas in the purification system condenser 360 to maintain or increase the rate of carbon dioxide liquid supplied to the product storage vessel 374.

In operation, the processing system 100, 200 is provided for processing the substrate using a supercritical carbon dioxide that has been formed using a purified carbon dioxide liquid. The processing system 100, 200 provides a purification system 300 that is coupled to the processing chamber 101. By coupling the purification system 300 to the processing chamber 101, a supply of purified carbon dioxide liquid that consistently meets or exceeds the target purity level is formed for use in processing the substrate with a supercritical carbon dioxide fluid. The purity level of the purified carbon dioxide liquid is critical to avoid contamination of the substrate being processed. The purification system 300 is configured with a product storage vessel 374 that includes a product level indication controller 390 that controls that amount of purified carbon dioxide in the product storage vessel 374 so that a ready supply of purified carbon dioxide liquid is available for use in processing the substrate. Combining the purification system 300 having the product storage vessel 374 with the processing chamber 101 minimizes contamination risks during the processing of the substrate with supercritical carbon dioxide fluid.

While the foregoing is directed to embodiments of the present disclosure, other and further embodiments of the disclosure may be devised without departing from the basic scope thereof, and the scope thereof is determined by the claims that follow.

1. A method of processing a substrate, comprising:
providing a feed supply of a carbon dioxide liquid;
supplying under pressure a feed stream of the carbon dioxide liquid from the feed supply to a purification vessel of a purification system;
supplying heat to the carbon dioxide liquid in the purification vessel with a distillation heater in the purification vessel;
distilling the carbon dioxide liquid in the purification vessel to form a purified carbon dioxide gas in a single stage distillation process;
supplying the purified carbon dioxide gas from the purification vessel to a purification system condenser through a distillation fluid line;
condensing the purified carbon dioxide gas in the purification system condenser by heat exchange with a refrigerant from a refrigeration system to form a purified carbon dioxide liquid;
heating the purified carbon dioxide liquid to a target temperature above a critical point to change the purified carbon dioxide liquid to a supercritical carbon dioxide fluid; and
using the supercritical carbon dioxide fluid to clean a substrate disposed in a processing chamber.

2. The method of claim 1, wherein the carbon dioxide liquid from the feed supply has a target impurity level of 5 parts per million by weight of non-volatile organic compounds, and wherein the purified carbon dioxide liquid has an impurity level that does not exceed 0.05 parts per million by weight of non-volatile organic compounds.

3. The method of claim 2, further comprising:
outputting exhaust fluid from the processing chamber; and
supplying the exhaust fluid to the purification system.

4. The method of claim 1, wherein cleaning the substrate comprises:
supplying the purified carbon dioxide liquid to the processing chamber having the substrate disposed therein; and
heating the purified carbon dioxide liquid to the target temperature in the processing chamber having the substrate disposed therein to change the purified carbon dioxide liquid to the supercritical carbon dioxide fluid.

5. The method of claim 1, wherein cleaning the substrate comprises:
heating the purified carbon dioxide liquid to the target temperature to change the purified carbon dioxide liquid to the supercritical carbon dioxide fluid; and
supplying through an inlet fluid supply line the supercritical carbon dioxide fluid to the processing chamber having the substrate disposed therein.

6. The method of claim 1, further comprising:
purging the purification system with a cleaning carbon dioxide gas prior to supplying the carbon dioxide liquid from the feed supply to the purification vessel, wherein the cleaning carbon dioxide gas has a minimum purity of 99.99 percent.

7. The method of claim 1, further comprising:
supplying the purified carbon dioxide liquid to a product storage vessel, wherein the carbon dioxide liquid in the product storage vessel has a purified liquid storage level;
generating a storage level control signal corresponding to the purified liquid storage level; and
controlling the purified liquid storage level in the product storage vessel by controlling the refrigerant supplied to the purification system condenser in response to the storage level control signal of the product storage vessel.

8. The method of claim 7, wherein controlling the purified liquid storage level in the product storage vessel further comprises controlling an evaporation rate of the carbon dioxide liquid in the purification vessel by controlling a heat output of the distillation heater in response to the storage level control signal.

9. The method of claim 1, further comprising:
supplying the purified carbon dioxide liquid to a product storage vessel; and
passing the purified carbon dioxide liquid from the product storage vessel through a subcooler prior to supplying the purified carbon dioxide liquid to the processing chamber.

10. The method of claim 1, further comprising:
supplying the purified carbon dioxide liquid to a product storage vessel; and
passing the purified carbon dioxide liquid from a product storage vessel through an adsorption filter prior to supplying the purified carbon dioxide liquid to the processing chamber.

11. A method of processing a substrate, comprising:
supplying under pressure a feed stream of a carbon dioxide liquid to a purification system having a purification vessel, a purification system condenser, a refrigeration system, and a product storage vessel;
distilling the carbon dioxide liquid in the purification vessel to form a purified carbon dioxide gas in a single stage distillation process;
supplying the purified carbon dioxide gas from the purification vessel to the purification system condenser through a distillation fluid line;
condensing the purified carbon dioxide gas in the purification system condenser by heat exchange with a refrigerant from a refrigeration system to form a purified carbon dioxide liquid;
supplying the purified carbon dioxide liquid to the product storage vessel;
heating the purified carbon dioxide liquid from the purification system to a target temperature above a critical point to change the purified carbon dioxide liquid to a supercritical carbon dioxide fluid;
using the supercritical carbon dioxide fluid to clean a substrate disposed in a processing chamber.

12. The method of claim 1, wherein the carbon dioxide liquid from the feed stream has a target impurity level of 5 parts per million by weight of non-volatile organic compounds, and wherein the purified carbon dioxide liquid has an impurity level that does not exceed 0.05 parts per million by weight of non-volatile organic compounds.

13. The method of claim 11, wherein cleaning the substrate comprises:
supplying the purified carbon dioxide liquid to the processing chamber having the substrate disposed therein; and
heating the purified carbon dioxide liquid to the target temperature above the critical point in the processing chamber having the substrate disposed therein to change the purified carbon dioxide liquid to the supercritical carbon dioxide fluid.

14. The method of claim 11, wherein cleaning the substrate comprises:
heating the purified carbon dioxide liquid to the target temperature above the critical point to change the purified carbon dioxide liquid to the supercritical carbon dioxide fluid; and
supplying through a supercritical fluid supply line the supercritical carbon dioxide fluid to the processing chamber having the substrate disposed therein.

15. The method of claim 11, further comprising:
supplying the purified carbon dioxide liquid to the product storage vessel, wherein the carbon dioxide liquid in the product storage vessel has a purified liquid storage level;
generating a storage level control signal corresponding to the purified liquid storage level;
controlling the purified liquid storage level in the product storage vessel by controlling the purified liquid storage level in the product storage vessel further comprises controlling an evaporation rate of the carbon dioxide liquid in the purification vessel by controlling a heat output of the distillation heater in response to the storage level control signal.

16. The method of claim 11, wherein controlling the purified liquid storage level in the product storage vessel further comprises controlling the refrigerant supplied to the purification system condenser in response to the storage level control signal of the product storage vessel so as to adjust a supply of the purified carbon dioxide liquid supplied from the purification system condenser.

17. A system for processing a substrate, comprising:
a purification system for purifying a feed supply of carbon dioxide liquid disposed in a feed supply container, wherein the purification system comprises:
a distillation unit having a purification vessel coupled to the feed supply container, wherein the distillation unit comprises a distillation heater disposed in the purification vessel for heating the carbon dioxide liquid disposed therein, wherein the distillation unit is configured to distill a feed stream of carbon dioxide liquid from the feed supply container in a single stage distillation process to form a purified carbon dioxide gas;
a purification system condenser coupled to the distillation unit by a distillation fluid line, wherein the purification system condenser is configured to receive the purified carbon dioxide gas supplied by the distillation fluid line and to condense the purified carbon dioxide gas in the purification system condenser by heat exchange with a refrigerant to form a purified carbon dioxide liquid;
a refrigeration system coupled to the purification system condenser by a refrigerant supply line to supply the refrigerant to the purification system condenser;
a processing chamber for processing a substrate disposed therein and coupled to the purification system by a purified carbon dioxide supply line, wherein the purified carbon dioxide supply line supplies a purified carbon dioxide fluid to the processing chamber; and
a heating element configured to heat the purified carbon dioxide liquid to a target temperature above a critical point to change the purified carbon dioxide liquid to a supercritical carbon dioxide fluid.

18. The system of claim 17, wherein the heating element is disposed proximate to the processing chamber and configured to heat the purified carbon dioxide fluid in the processing chamber to form the supercritical carbon dioxide fluid in the processing chamber.

19. The system of claim 17, wherein the heating element is disposed proximate the purified carbon dioxide supply line to heat the purified carbon dioxide liquid in the purified carbon dioxide supply line to form the supercritical carbon dioxide fluid.

20. The system of claim 17, further comprising:
a product storage vessel coupled to the purification system condenser by a condenser liquid supply line, wherein the purification system condenser supplies the purified carbon dioxide liquid to the product storage vessel through the condenser liquid supply line for storage of the purified carbon dioxide liquid in the product storage vessel, and wherein the purified carbon dioxide liquid in the product storage vessel has a purified liquid storage level;
a refrigerant control valve disposed in the refrigerant supply line to control refrigerant flow to the purification system condenser;
a heater controller coupled to the distillation heater;
a product level indication controller coupled to the refrigerant control valve and the heater controller, the product level indication controller configured to communicate to the refrigerant control valve and the heater controller a storage level control signal corresponding to the purified liquid storage level; and
wherein the refrigerant control valve is configured to adjust a refrigerant flow rate to the purification system condenser in response to the storage level control signal and the heater controller is configured to adjust a heat output of the distillation heater in response to the storage level control signal so as to adjust a supply of the purified carbon dioxide liquid supplied from the purification system condenser.
